(19) United States
(12) Patent Application Publication
(10) Pub. No.: US 2007/0206718 A1
(43) Pub. Date: Sep. 6, 2007

(54) Register circuit, semiconductor device, and electric appliance

(76) Inventor: Tomokazu Okada, Kyoto-shi (JP)

Correspondence Address: FISH & RICHARDSON P.C., P.O. BOX 1022, MINNEAPOLIS, MN, 55440-1022, US

(21) Appl. No.: 11/700,651

(22) Filed: Jan. 30, 2007

(30) Foreign Application Priority Data
Mar. 2, 2006 (JP) 2006-056023

(51) Int. Cl. G11C 19/00

(52) U.S. Cl. 377/64

(57) ABSTRACT

A register circuit is provided with a register portion composed of a plurality of latches or flip-flops whose data input terminals are connected together and whose clock input terminals are connected together, and a coincidence checker that checks whether or not the output signals of the plurality of latches or flip-flops coincide with each other. Here, the register circuit is so configured as to send an output signal of the coincidence checker to the following stage as a final register output. With this configuration, it is possible to improve the noise immunity of the register circuit without delaying output response to an input of a normal signal.

This application is based on Japanese Patent Application No. 2006-056023 filed on Mar. 2, 2006, the contents of which are hereby incorporated by reference.

### BACKGROUND OF THE INVENTION

1. Field of the Invention

The present invention relates to a register circuit that holds an input data signal according to a clock signal and to a semiconductor device and an electric appliance provided with such a register circuit, and more particularly to an anti-noise technology thereof.

2. Description of Related Art

FIG. 12 is a block diagram showing an example of a conventional register circuit. As shown in this figure, this conventional register circuit is so configured as to hold an input data signal Di according to a clock signal CL by using a single flip-flop FF, for example, and to send an output signal So of the flip-flop FF to the following stage as a final register output.

As another conventional technology related to what has been described thus far, there have been disclosed, for example, in Patent Document 1 (JP-A-H7-298092) and Patent Document 2 (JP-A-H11-031954).

Patent Document 1 discloses and proposes a vertical synchronizing signal separation circuit that performs detection of a vertical synchronizing signal at two different times by using two different clock pulses, that judges, only when a vertical synchronizing signal is detected with different timing, that this is a normal vertical synchronizing signal, and that permits the output thereof.

Patent Document 2 discloses and proposes a clock signal detection circuit composed of first and second holding means that hold a detection signal outputted from first and second comparing means when a clock signal and an inverting clock signal change, and that outputs a stable, noiseless clock detection signal by checking a detection signal held in the first and second holding means.

It is true that the register circuit shown in FIG. 12 makes it possible to hold the logic level of the input data signal Di with a simple configuration.

However, in the conventional register circuit described above, if the output signal So of the flip-flop FF changes to an unintended logic state due to the application of static electricity or the superimposition of noise, the output signal So in an erroneous logic state is held until the next trigger edge of the clock signal CL arrives, as shown in FIG. 13, and thus there is a possibility that this results in abnormal operation of an electric appliance provided with such a register circuit.

Some examples of the measures to prevent the abnormal operation described above are, for example, the implementation of anti-noise measures by analog means or the change of operational specifications of the circuit provided in the following stage based on the output signal So. However, since the former often results in an increase of the device size and the latter imposes inconvenience on the user, they are not necessarily the best measures.

The conventional technologies disclosed in Patent Documents 1 and 2 appear to be similar in configuration to the present invention in that both of them take the AND of the outputs of a plurality of flip-flops connected in parallel and generate a final output. However, the former is a technology for improving the accuracy of separation of a vertical synchronizing signal, and the latter is a technology for obtaining a stable clock detection signal by discarding a changing, unstable comparison result. Thus, both of them have different problems to be solved and objects from the present invention, and accordingly they are fundamentally different from the present invention in configuration.

In particular, unlike the present invention, the conventional technologies disclosed in Patent Documents 1 and 2 are so configured as to perform detection of an input signal at two different times with different timing. Thus, when these conventional technologies are applied to a register circuit as anti-noise measures, although it is possible to avoid an unintended logic level change of a register output, this results in delay in output response to an input of a normal signal and accordingly makes it impossible to immediately perform normal operation based on the register output. Therefore, these conventional technologies are not always the suitable measures.

### SUMMARY OF THE INVENTION

In view of the conventionally experienced problems described above, it is an object of the present invention to provide a register circuit that can improve the noise immunity thereof without delaying output response to an input of a normal signal, and to provide a semiconductor device and an electric appliance provided with such a register circuit.

To achieve the above object, according to the present invention, a register circuit is provided with a register portion composed of a plurality of latches or flip-flops whose data input terminals are connected together and whose clock input terminals are connected together, and a coincidence checker that checks whether or not the output signals of the plurality of latches or flip-flops coincide with each other. Here, the register circuit is so configured as to send an output signal of the coincidence checker to the following stage as a final register output.

Other features, elements, steps, advantages and characteristics of the present invention will become more apparent from the following detailed description of preferred embodiments thereof with reference to the attached drawings.

### BRIEF DESCRIPTION OF THE DRAWINGS

FIG. 1 is a block diagram showing a first embodiment of the register circuit embodying the present invention;

FIG. 2 is a diagram illustrating normal operation of a register circuit 100;

FIG. 3 is a diagram illustrating noise immunity improvement operation of the register circuit 100;

FIG. 4 is a block diagram showing a second embodiment of the register circuit embodying the present invention;

FIG. 5 is a block diagram showing a third embodiment of the register circuit embodying the present invention;

FIG. 6 is a diagram illustrating normal operation of a register circuit 120;

FIG. 7 is a diagram illustrating noise immunity improvement operation of the register circuit 120;

FIG. 8 is a layout diagram showing, in a plan view, an example of the arrangement of flip-flops;

FIG. 9 is a block diagram showing one embodiment of a semiconductor device provided with the register circuit embodying the present invention and of an electric appliance built with such a semiconductor device;

FIG. 10 is a diagram illustrating the correlation between an operating status signal sel1 and a monitoring level setting signal sel2;

FIG. 11 is a flow chart showing the operation performed by a monitoring circuit 200 to generate an enable signal ENa;

FIG. 12 is a block diagram showing an example of the conventional register circuit; and

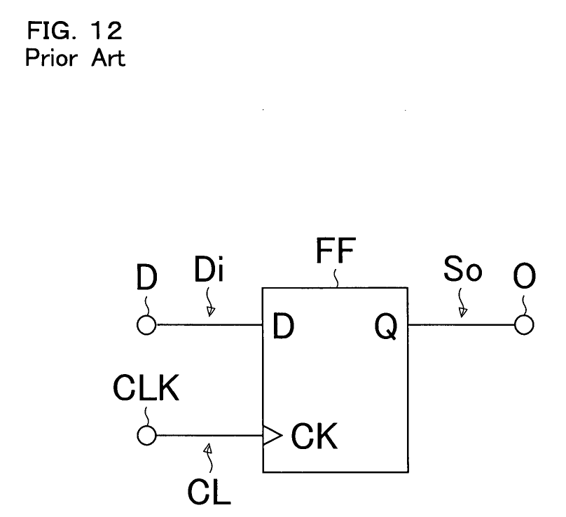

FIG. 13 is a waveform diagram illustrating how an unintended logic level change of an output signal So occurs.

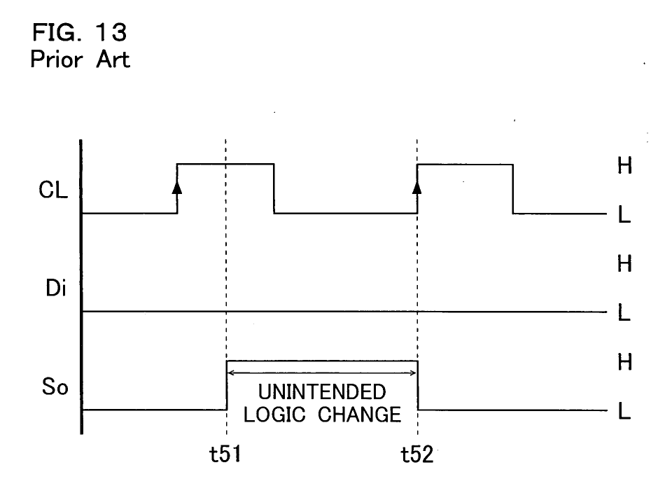

### DETAILED DESCRIPTION OF PREFERRED EMBODIMENTS

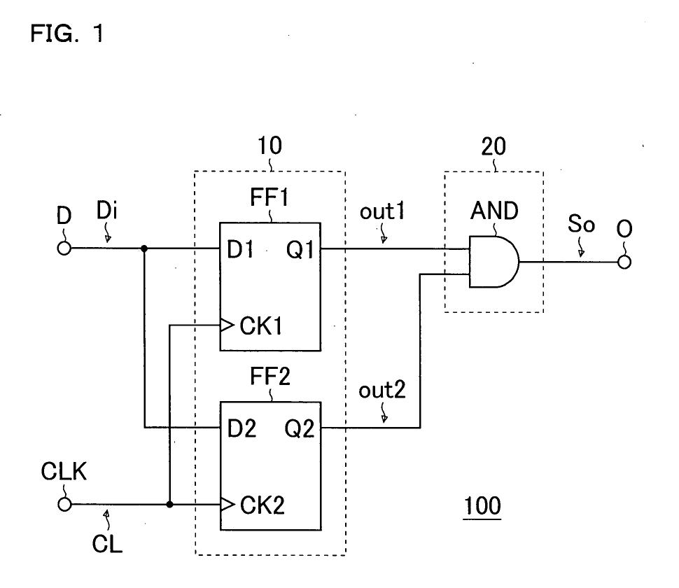

Hereinafter, a first embodiment of the register circuit embodying the present invention will be described in detail with reference to FIG. 1.

FIG. 1 is a block diagram showing the first embodiment of the register circuit embodying the present invention.

As shown in this figure, a register circuit 100 of this embodiment is composed of a register portion 10 built with two flip-flops FF1 and FF2 whose data input terminals are connected together and whose clock input terminals are connected together, and a coincidence checker 20 that checks whether or not output signals out1 and out2 of the flip-flops FF1 and FF2 coincide with each other (i.e. whether or not the logic level change of the output signals out1 and out2 occurs simultaneously). The register circuit 100 is so configured as to send an output signal So of the coincidence checker 20 to the following stage as a final register output.

Now, the connection relationship between the circuit blocks described above will be described more specifically. The data input terminals (D1 and D2) of the flip-flops FF1 and FF2 are connected to a terminal D to which an input data signal Di is applied. The clock input terminals (CK1 and CK2) of the flip-flops FF1 and FF2 are connected to a terminal CLK to which a clock signal CL is applied. Data output terminals (Q1 and Q2) of the flip-flops FF1 and FF2 are each connected to one of two input terminals of an AND logic unit AND that forms the coincidence checker 20. The output terminal of the AND logic unit AND is connected to a terminal O from which an output signal So is extracted.

The flip-flops FF1 and FF2 are both so configured as to change the logic levels of the output signals out1 and out2, respectively, according to the input data signal Di by using a rising edge of the clock signal CL as a trigger edge, and to maintain the current output logic level until the next rising edge arrives.

The AND logic unit AND turns the output signal So to a high level only when the output signals out1 and out2 described above both take a high level, and otherwise the AND logic unit AND turns the output signal So to a low level.

As described above, a configuration in which an AND logic unit AND is used as the coincidence checker 20 makes it possible to easily check whether or not the output signals out1 and out2 coincide with each other (i.e. whether or not they are changed to a high level simultaneously).

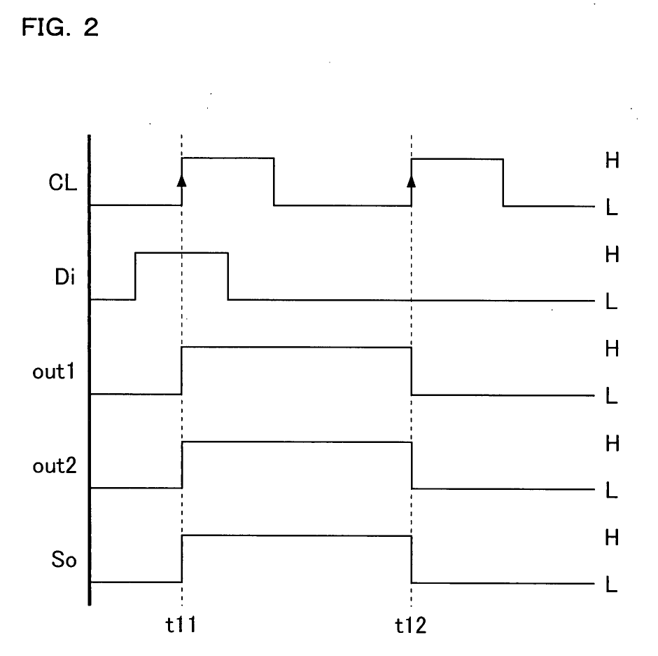

Next, normal operation (register operation performed when the input data signal Di is activated by the normal flow) of the register circuit 100 configured as described above will be described in detail with reference to FIG. 2.

FIG. 2 is a timing chart illustrating the normal operation of the register circuit 100.

As shown in FIG. 2, when the input data signal Di is activated (in this embodiment, takes a high level), in the flip-flops FF1 and FF2, the logic levels of the output signals out1 and out2 are changed according to the input data signal Di by using, as a trigger edge, a rising edge of the clock signal CL that arrives (in this figure, at time t11) immediately after the input data signal Di is activated, and the logic states of the output signals out1 and out2 are maintained until the next trigger edge arrives (in this figure, at time t12).

That is, in the flip-flops FF1 and FF2, at time t11, the input data signal Di applied to the data input terminals D1 and D2 is transmitted as the output signals out1 and out2, and the logic states thereof are changed from a low level to a high level. Thus, the output signal So of the AND logic unit AND is changed from a low level to a high level at time t11 without delay, and the logic state thereof is maintained until time t12.

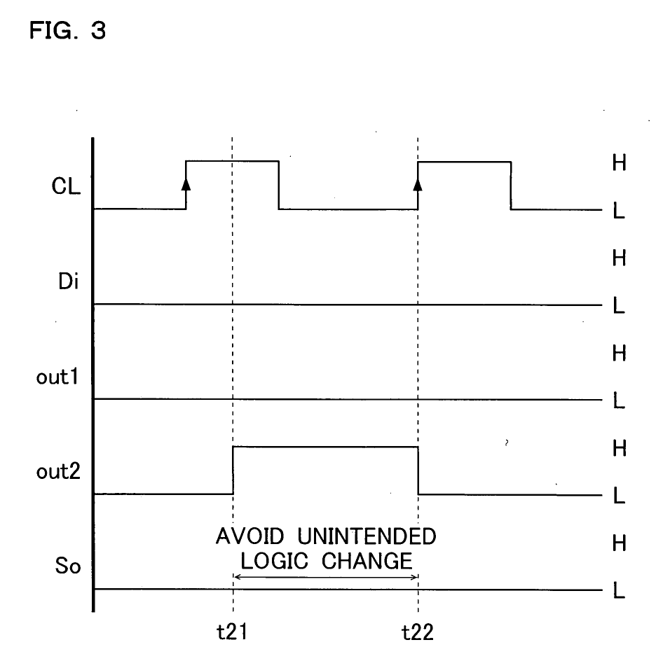

Next, noise immunity improvement operation (register operation performed when an unintended logic level change occurs in one of the output signals out1 and out2 due to the application of static electricity or the superimposition of noise) of the register circuit 100 configured as described above will be described in detail with reference to FIG. 3.

FIG. 3 is a timing chart illustrating the noise immunity improvement operation of the register circuit 100.

As shown in FIG. 3, when the output signal out2 of the flip-flop FF2 is unintentionally changed from a low level to a high level at time t21 due to the application of static electricity or the superimposition of noise, the output signal out2 is maintained in an erroneous logic state from time t21 onward until the next trigger edge arrives (in this figure, at time t22). On the other hand, unlike the flip-flop FF2, in the flip-flop FF1, the output signal out1 thereof is maintained in a normal logic state (a low level).

That is, for this embodiment in which the register portion 10 is composed of a plurality of flip-flops FF1 and FF2, even when static electricity is applied or noise is superimposed, the chances of both of the output signals out1 and out2 simultaneously suffering from an unintended logic level change are understandably lower than the chances of one of those output signals suffering therefrom.

As described above, the AND logic unit AND turns the output signal So to a high level only when the output signals out1 and out2 both take a high level.

Thus, in the register circuit 100 of this embodiment, even when one of the output signals out1 and out2 suffers from an unintended logic level change, a final output signal So of the register circuit 100 is maintained in a normal logic state (a low level) unless both of the output signals suffer from an unintended logic level change.

As described above, with the register circuit 100 of this embodiment, it is possible to avoid an unintended logic level change of the output signal So even when static electricity is applied or noise is superimposed. This helps improve the noise immunity of the register circuit 100. Moreover, with the register circuit 100 of this embodiment, it is possible to perform register output without delay when the input data signal Di changes to a high level by the normal flow. This makes it possible for the circuit provided in the following stage to which the output signal So is inputted to immediately perform normal operation based on the inputted output signal So.

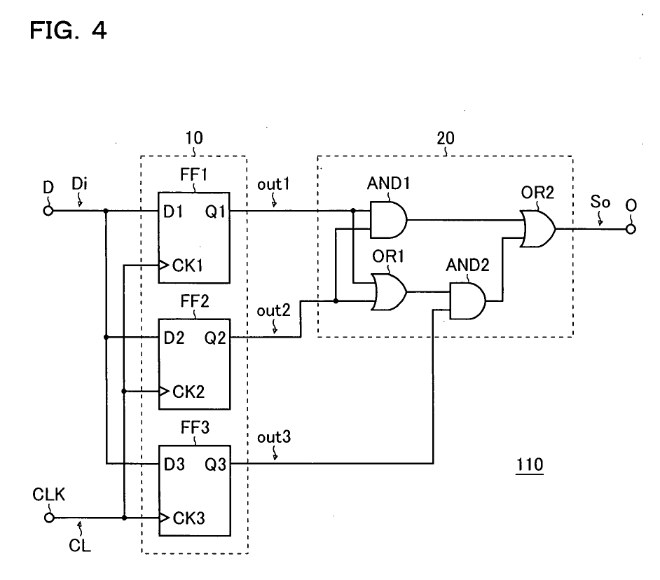

Next, a second embodiment of the register circuit embodying the present invention will be described in detail with reference to FIG. 4.

FIG. 4 is a block diagram showing the second embodiment of the register circuit embodying the present invention.

As shown in this figure, a register circuit 110 of this embodiment is configured in almost the same manner as in the first embodiment described above. Therefore, here, such circuit blocks as are found also in the first embodiment are identified with the same reference characters, and their explanations will not be repeated. Hereinafter, explanations will be given with emphasis placed on the configuration which characterizes this embodiment.

First, the register circuit 110 of this embodiment is characterized in that, unlike the first embodiment described above, a register portion 10 is composed of three flip-flops FF1 to FF3. As compared with the first embodiment, such an increase in the number of flip-flops connected in parallel helps further reduce the chances of all the output signals out1 to out3 simultaneously suffering from an unintended logic level change. This make it possible to further improve the noise immunity of the register circuit 110.

Secondly, the register circuit 110 of this embodiment is characterized in that, unlike the first embodiment described above, a coincidence checker 20 is configured as a majority operation circuit that performs majority operation on the output signals out1 to out3. Here, the majority operation circuit can be composed of, for example, AND logic units AND1 and AND2 and OR logic units OR1 and OR2.

Now, the connection relationship between the circuit blocks described above will be described more specifically. One input terminal of the AND logic unit AND1 is connected to a data output terminal (Q1) of the flip-flop FF1, and the other input terminal of the AND logic unit AND1 is connected to a data output terminal (Q2) of the flip-flop FF2. One input terminal of the AND logic unit AND2 is connected to the output terminal of the OR logic unit OR1, and the other input terminal of the AND logic unit AND2 is connected to a data output terminal (Q3) of the flip-flop FF3. One input terminal of the OR logic unit OR1 is connected to the data output terminal (Q1) of the flip-flop FF1, and the other input terminal of the OR logic unit OR1 is connected to the data output terminal (Q2) of the flip-flop FF2. One input terminal of the OR logic unit OR2 is connected to the output terminal of the AND logic unit AND1, and the other input terminal of the OR logic unit OR2 is connected to the output terminal of the AND logic unit AND2. The output terminal of the OR logic unit OR2 is connected to a terminal O from which an output signal So is extracted.

The majority circuit configured as described above turns the output signal So to a high level only when at least two of the output signals out1 to out3 of the flip-flops FF1 to FF3 take a high level, and otherwise the majority circuit turns the output signal So to a low level.

As described above, with a configuration in which a majority circuit is used as the coincidence checker 20, even if the output response of one of the flip-flops FF1 to FF3 is delayed when the input data signal Di changes to a high level by the normal flow, it is judged that the output signals out1 to out3 coincide with each other. This makes it possible to perform register output without delay. As a result, the circuit provided in the following stage to which the output signal So is inputted can immediately perform normal operation based on the inputted output signal So. In particular, in a case where the number of flip-flops that form the register portion 10 is increased, for example, from three to five, from five to seven, . . . , it is believed that the use of a majority circuit as the coincidence checker 20 is more preferable.

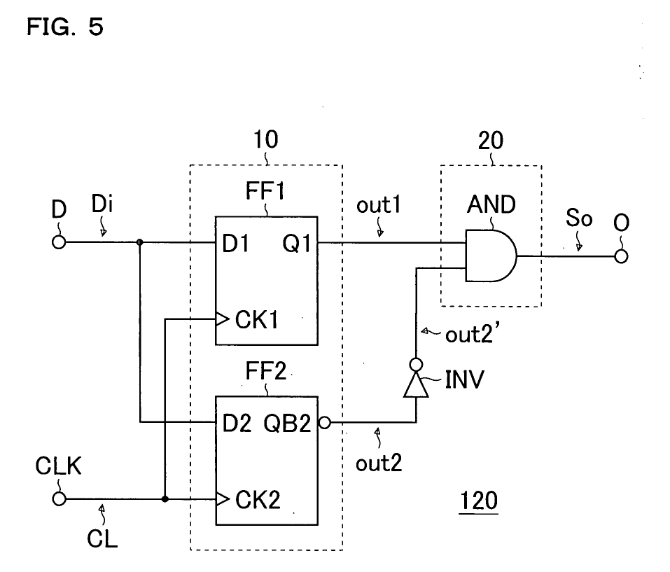

Next, a third embodiment of the register circuit embodying the present invention will be described in detail with reference to FIG. 5.

FIG. 5 is a block diagram showing the third embodiment of the register circuit embodying the present invention.

As shown in this figure, a register circuit 120 of this embodiment is configured in almost the same manner as in the first embodiment described above. Therefore, here, such circuit blocks as are found also in the first embodiment are identified with the same reference characters, and their explanations will not be repeated. Hereinafter, explanations will be given with emphasis placed on the configuration which characterizes this embodiment.

The register circuit 120 of this embodiment is characterized in that, unlike the first embodiment described above, it is provided with both a non-inverting output flip-flop FF1 and an inverting output flip-flop FF2 as flip-flops FF1 and FF2 that form a register portion 1. Of the output signals out1 and out2 of the flip-flops FF1 and FF2, a non-inverting output signal out1 is directly inputted to a coincidence checker 20, and an inverting output signal out2 is inputted, after the logic level thereof is re-inverted by an inverter INV, to the coincidence checker 20 as a non-inverting output signal out2′.

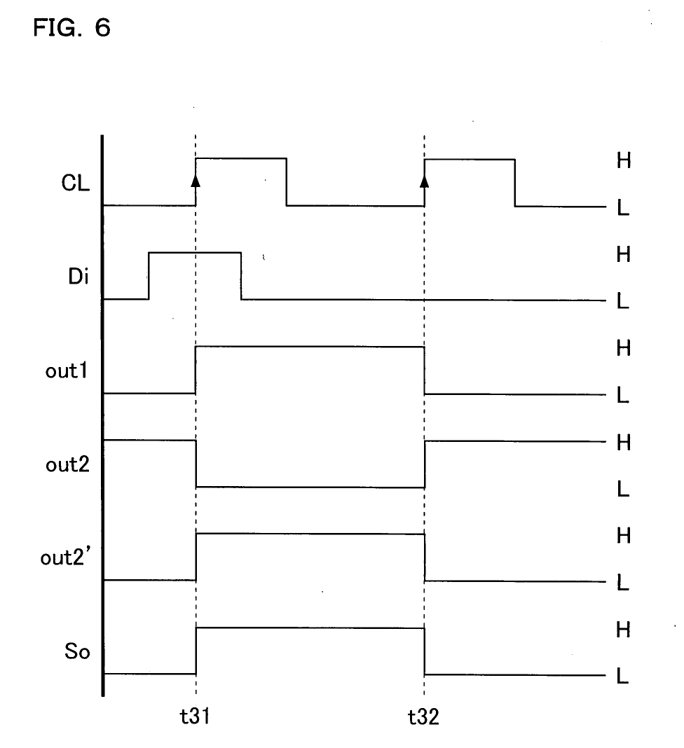

Next, normal operation (register operation performed when the input data signal Di is activated by the normal flow) of the register circuit 120 configured as described above will be described with reference to FIG. 6.

FIG. 6 is a timing chart illustrating the normal operation of the register circuit 120.

As shown in FIG. 6, when the input data signal Di is activated (in this embodiment, takes a high level), in the flip-flops FF1 and FF2, the logic levels of the output signals out1 and out2 are changed according to the input data signal Di by using, as a trigger edge, a rising edge of the clock signal CL that arrives (in this figure, at time t31) immediately after the input data signal Di is activated, and the logic states of the output signals out1 and out2 are maintained until the next trigger edge arrives (in this figure, at time t32).

That is, in the flip-flop FF1, at time t31, the input data signal Di applied to the data input terminal D1 is transmitted as the output signal out1, and the logic state thereof is changed from a low level to a high level. On the other hand, in the flip-flop FF2, at time t31, an inverted logic level signal of the input data signal Di applied to the data input terminal D2 is transmitted as the output signal out2, and the logic state thereof is changed from a high level to a low level. In the inverter INV, the output signal out2′ obtained by re-inverting the logic level of the output signal out2 is generated, and the logic state thereof is changed from a low level to a high level. Thus, the output signal So of the AND logic unit AND is changed from a low level to a high level at time t31 without delay, and the logic state thereof is maintained until time t32.

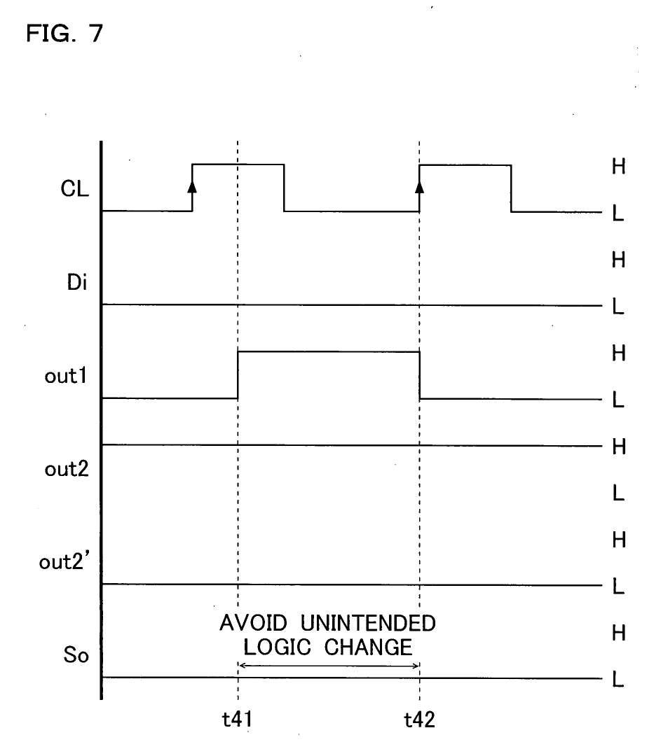

Next, noise immunity improvement operation (register operation performed when an unintended logic level change occurs in one of the output signals out1 and out2 due to the application of static electricity or the superimposition of noise) of the register circuit 120 configured as described above will be described in detail with reference to FIG. 7.

FIG. 7 is a timing chart illustrating the noise immunity improvement operation of the register circuit 120.

As shown in FIG. 7, when the output signal out1 of the flip-flop FF1 is unintentionally changed from a low level to a high level at time t41 due to the application of static electricity or the superimposition of noise, the output signal out1 is maintained in an erroneous logic state from time t41 onward until the next trigger edge arrives (in this figure, at time t42). On the other hand, unlike the flip-flop FF1, in the flip-flop FF2, the output signal out2 thereof is maintained in a normal logic state (a high level).

That is, for this embodiment in which the register portion 10 is composed of a plurality of flip-flops FF1 and FF2, even when static electricity is applied or noise is superimposed, the chances of both of the output signals out1 and out2 simultaneously suffering from an unintended logic level change are understandably lower than the chances of one of those output signals suffering therefrom.

In a case where the output signals out1 and out2 tend to change to one logic state (for example, a high level) due to variations in characteristics among transistors on a wafer (variations in threshold voltages of the transistors), in the first embodiment described above, there is a possibility that both of the output signals out1 and out2 easily suffer from an unintended logic level change simultaneously. By contrast, as a result of the register circuit 120 of this embodiment being provided with both a non-inverting output flip-flop FF1 and an inverting output flip-flop FF2, the register circuit 120 can not only eliminate the above-described possibility but also make lower the chances of both of the output signals out1 and out2 simultaneously suffering from an unintended logic level change as compared with the first embodiment.

Thus, with the register circuit 120 of this embodiment, it is possible not only to achieve the same effects as those achieved in the first embodiment, but also to further improve the noise immunity thereof by taking advantage of variations in characteristics among transistors.

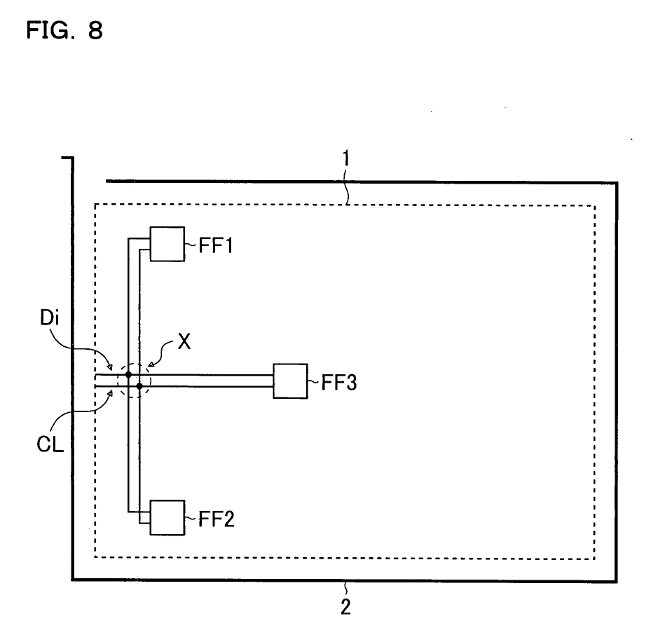

Next, the arrangement of flip-flops that form the register portion 10 will be described in detail with reference to FIG. 8.

FIG. 8 is a layout diagram showing, in a plan view, an example of the arrangement of the flip-flops.

In this figure, a circuit block 1 is a logic circuit block that is composed mainly of gate circuits, such as sequential circuits and AND logic units. In this circuit block 1, a plurality of flip-flops (in this figure, three flip-flops FF1 to FF3) that form the register portion 10 are arranged. The circuit block 1 is surrounded with low-impedance conductors 2 (power supply conductors or grounded conductors) in order to improve the noise immunity thereof.

In this case, advisably, in the circuit block 1 described above, as shown in this figure, the flip-flops FF1 to FF3 are arranged away from each other. With this arrangement, as compared with when the flip-flops FF1 to FF3 are arranged adjacent to each other, the same noise is prevented from being superimposed on them. This makes it possible to reduce the chances of all the output signals out1 to out3 simultaneously suffering from an unintended logic level change.

Advisably, in the circuit block 1 described above, as shown in this figure, the flip-flops FF1 to FF3 are arranged in such a way that the conductor lengths from a signal branch part X at which the data input terminals thereof are connected together and the clock input terminals thereof are connected together to the respective flip-flops FF1 to FF3 are equal to each other. With this arrangement, it is possible to suppress variations in delay time of the input data signal Di and the clock signal CL among the flip-flops FF1 to FF3.

Advisably, the flip-flops FF1 to FF3 are arranged as near the edge of the circuit block 1 as possible (that is, near the low-impedance conductor 2). With this arrangement, in this figure, it is possible to reduce the influence of noise on the flip-flops FF1 and FF2 arranged near the low-impedance conductor 2 as much as possible.

This figure deals with a configuration in which the circuit block 1 is surrounded with the low-impedance conductors 2. However, the present invention is not limited to this specific configuration. The low-impedance conductors 2 may be provided inside the circuit block 1. With this conductor layout, in this figure, it is possible to reduce the influence of noise on the flip-flop FF3 arranged at the center of the circuit block 1.

Advisably, as shown in this figure, the input data signal Di and the clock signal CL are inputted from the center of one side of the circuit block 1. With this conductor layout, it is possible to reduce the influence of noise on those signals as much as possible.

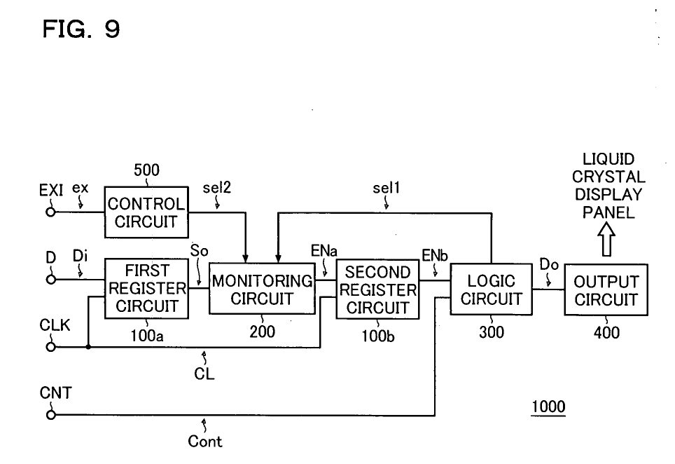

Next, a semiconductor device provided with the register circuit embodying the present invention and an electric appliance built with such a semiconductor device will be described in detail with reference to FIG. 9.

FIG. 9 is a block diagram showing one embodiment of a semiconductor device provided with the register circuit embodying the present invention and of an electric appliance (in this figure, a mobile apparatus provided with a liquid crystal display panel) built with such a semiconductor device.

As shown in this figure, the electric appliance to which the present invention is applied is composed of a liquid crystal display panel, which is a controlled apparatus, and a semiconductor device 1000 that controls the operations of the liquid crystal display panel.

The semiconductor device 1000 is composed of first and second register circuits 100a and 100b, a monitoring circuit 200, a logic circuit 300, an output circuit 400, and a control circuit 500, and, prior to read operation of a control signal Cont, which will be described later, and generation operation of an output data signal Do according to the control signal Cont, receives an input data signal Di as a signal for initializing the liquid crystal display panel.

The first register circuit 100a functions as a means for holding the input data signal Di according to the clock signal CL, and is configured in a similar manner as one of the register circuits 100 to 120 described above.

The monitoring circuit 200 functions as a means for receiving an output signal So of the first register circuit 100a, an operating status signal sel1 indicating the operating status of the liquid crystal display panel, and a monitoring level setting signal sel2 used for setting requirements for permission to generate an enable signal ENa, and generating the enable signal ENa according to the output signal So (that is, the input data signal Di) only when the operating status of the liquid crystal display panel satisfies the requirements for permission to generate the enable signal ENa. It is to be noted that the operation performed by the monitoring circuit 200 to generate the enable signal ENa will be described later in detail.

The second register circuit 100b functions as a means for holding the enable signal ENa according to the clock signal CL, and, as is the case with the first register circuit 100a, is configured in a similar manner as one of the register circuits 100 to 120 described above.

That is, the semiconductor device 1000 of this embodiment has a configuration in which, for the sake of realizing satisfactory anti-noise measures, the present invention is applied to both the first register circuit 100a provided in the previous stage of the monitoring circuit 200 and the second register circuit 100b provided in the following stage of the monitoring circuit 200.

This figure deals with a case in which the same clock signal CL is inputted to the first and second register circuits 100a and 100b. However, the present invention is not limited to this specific configuration. Different clock signals may be inputted to the first and second register circuits 100a and 100b.

The logic circuit 300 is so configured that, based on the enable signal ENb outputted from the second register circuit 100b, the read operation of the control signal Cont and the generation operation of the output data signal Do according to the control signal Cont are permitted/prohibited, and also functions as a means for generating the operating status signal sel1 one after another based on the operating status of the liquid crystal display panel.

The control signal Cont, which includes the designation of an address of the liquid crystal display panel or display data, may be inputted in a serial or parallel manner. Likewise, the output data signal Do may be outputted in a serial or parallel manner.

The logic circuit 300 may be so configured that the read operation of the control signal Cont and the generation operation of the output data signal Do according to the control signal Cont are permitted when the enable signal ENb outputted from the second register circuit 100b is activated. Instead, the logic circuit 300 may be so configured that those operations are prohibited when the enable signal ENb is activated.

The output circuit 400 functions as a means for controlling the operations of the liquid crystal display panel based on the output data signal Do described above.

The control circuit 500 functions as a means for generating the monitoring level setting signal sel2 according to an external instruction ex.

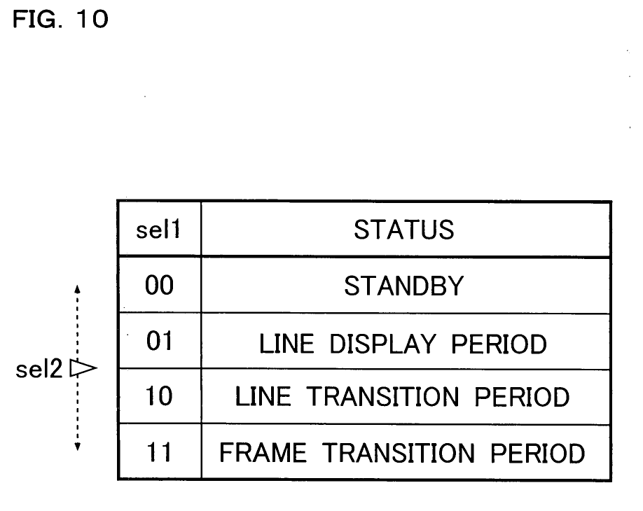

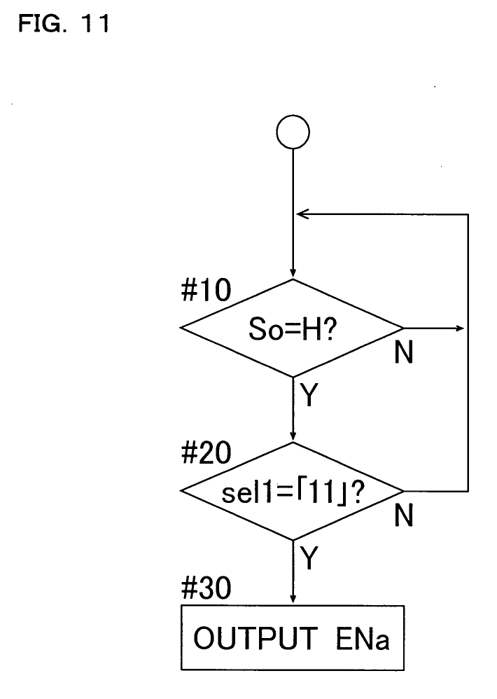

Next, the operation performed by the monitoring circuit 200 to generate the enable signal ENa will be described in detail with reference to FIGS. 10 and 11.

FIG. 10 is a diagram illustrating the correlation between the operating status signal sel1 and the monitoring level setting signal sel2, and FIG. 11 is a flow chart showing the operation performed by the monitoring circuit 200 to generate the enable signal ENa.

In an example shown in FIG. 10, the operating status of the liquid crystal display panel is classified, based on the operating status signal sel1, into four levels: status “00”, status “01”, status “10”, and status “11”.

Status “00” indicates that the logic circuit 300 is not receiving an input of the control signal Cont (a standby status). Status “01” indicates that the liquid crystal display panel is displaying one line (a line display period). Status “10” indicates that the liquid crystal display panel completes displaying one line and is ready for displaying the next line (a line transition period). The status “11” indicates that the liquid crystal display panel completes displaying one frame and is ready for displaying the next frame (a frame transition period).

On the other hand, as described above, the monitoring level setting signal sel2 is a signal used for setting requirements for permission to generate the enable signal ENa. In the monitoring circuit 200, only when the operating status of the liquid crystal display panel identified based on the operating status signal sel1 mentioned above satisfies the above-described requirements that are set based on the monitoring level setting signal sel2, the enable signal ENa according to the output signal So (that is, the input data signal Di) of the first register circuit 100a is generated.

Here, as is the case with the operating status signal sel1 mentioned above, the monitoring level setting signal sel2 of this embodiment sets the requirements for permission to generate the enable signal ENa on a step-by-step basis in such a way as to permit the generation of the enable signal ENa if the liquid crystal display panel is in status “11”, or to permit the generation of the enable signal ENa if the liquid crystal display panel is in status “10”.

Now, a detailed description will be given with reference to the flow chart in FIG. 11. This flow chart shows a case where it is permitted to generate the enable signal ENa only when the liquid crystal display panel is in status “11”.

As shown in this figure, prior to the generation of the enable signal ENa, the monitoring circuit 200 checks, in step #10, whether or not the output signal So (that is, the input data signal Di) of the first register circuit 100a takes a high level. When the output signal So is found to take a high level, the flow proceeds to step #20. On the other hand, when the output signal So is found not to take a high level, the flow goes back to step #10, and the monitoring circuit 200 continuously checks whether the output signal So is activated or not.

When the output signal So is found to take a high level in step #10, it is checked, in step #20, whether the operating status of the liquid crystal display panel is status “11” or not based on the current operating status signal sel1. When the operating status of the liquid crystal display panel is found to be status “11”, the flow proceeds to step #30, and the enable signal ENa is generated and outputted. On the other hand, when the operating status of the liquid crystal display panel is found not to be status “11”, the flow goes back to step #10, and the monitoring circuit 200 continuously checks whether the output signal So is activated or not.

The monitoring circuit 200 described above allows the enable signal ENa to be generated only when the operating status of the liquid crystal display panel is a frame transition period. This makes it possible to prevent images on the display screen of the liquid crystal display panel from being discontinuously displayed or distorted at the time of initialization of the liquid crystal display panel.

The semiconductor device 1000 of this embodiment is provided with the control circuit 500 as a means for generating the monitoring level setting signal sel2 as appropriate according to an external instruction ex and arbitrarily controlling the requirements for permission to generate the enable signal ENa. Thus, in a case where some distortion of the images on the display screen causes no problem, it is possible, by easing the requirements for permission to generate the enable signal ENa, to give instructions to permit the initialization of the liquid crystal display panel even if the operating status thereof is status “10” or “01”.

The embodiment described above deals with a case where the present invention is applied to a mobile apparatus provided with a liquid crystal display panel. It is to be understood, however, that the present invention is applicable also to electric appliances of other types.

For example, the present invention is suitable for use in data transmission apparatuses that receive, prior to generation and transmission of transmitted data according to a control signal Cont, an input data signal Di based on the user operation as an operation trigger, or data reception apparatuses that receive, prior to decoding of received data according to a control signal Cont, an input data signal Di based on the received data as an operation trigger.

Obviously, many modifications and variations of the present invention are possible in light of the above teachings. It is therefore to be understood that within the scope of the appended claims, the invention may be practiced other than as specifically described.

For example, the embodiment described above deals with a case where a flip-flop is used as a sequential circuit that forms the register portion 10. However, the present invention is not limited to this specific configuration. The register portion 10 may be composed of a plurality of latches.

Moreover, the embodiment described above deals with a case where the register portion 10 is composed of two or three flip-flops. However, the present invention is not limited to this specific configuration. Four or more sequential circuits that form the register portion 10 may be provided in parallel.

Needless to say, the register circuit of the present invention can be applied to a semiconductor device that is not provided with the monitoring circuit 200 and the control circuit 500 described above, that is, a semiconductor device composed of a register circuit that holds an input data signal according to a clock signal and a logic circuit that is so configured that, based on an output signal of the register circuit, read operation of a control signal and generation operation of an output data signal according to the control signal are permitted/prohibited.

As described above, with the register circuit of the present invention, by reviewing the configuration thereof from a logical standpoint, it is possible to improve the noise immunity thereof without delaying output response to an input of a normal signal. This eventually enhances the reliability of a semiconductor device and an electric appliance provided with such a register circuit.

While the present invention has been described with respect to preferred embodiments, it will be apparent to those skilled in the art that the disclosed invention may be modified in numerous ways and may assume many embodiments other than those specifically set out and described above. Accordingly, it is intended by the appended claims to cover all modifications of the present invention which fall within the true spirit and scope of the invention.

For industrial applicability, the present invention is useful in improving the noise immunity of a register circuit, and is applicable to all kinds of sequential circuits.

What is claimed is:

1. A register circuit comprising:
a register portion composed of a plurality of latches or flip-flops whose data input terminals are connected together and whose clock input terminals are connected together; and
a coincidence checker that checks whether or not output signals of the plurality of latches or flip-flops coincide with each other, wherein
the register circuit sends an output signal of the coincidence checker to a following stage as a final register output.

2. The register circuit of claim 1, wherein
the register circuit includes, as the coincidence checker, an AND logic unit that takes an AND of the output signals of the plurality of latches or flip-flops, or a majority operation circuit that performs majority operation on the output signals of the plurality of latches or flip-flops.

3. The register circuit of claim 1, wherein
the register circuit includes, as the plurality of latches or flip-flops, both a non-inverting output latch or flip-flop and an inverting output latch or flip-flop, and
of the output signals of the plurality of latches or flip-flops, a non-inverting output signal is directly inputted to the coincidence checker, and an inverting output signal is inputted, after a logic level thereof is re-inverted, to the coincidence checker.

4. The register circuit of claim 1, wherein
in a circuit block, the plurality of latches or flip-flops are arranged away from each other.

5. The register circuit of claim 4, wherein
in the circuit block, the plurality of latches or flip-flops are arranged in such a way that conductor lengths from a signal branch part at which the data input terminals thereof are connected together and the clock input terminals thereof are connected together to the respective latches or flip-flops are equal to each other.

6. A semiconductor device comprising:
a register circuit that holds an input data signal according to a clock signal; and
a logic circuit that is so configured that, based on an output signal of the register circuit, read operation of a control signal and generation operation of an output data signal according to the control signal are permitted/prohibited, wherein
the register circuit includes
a register portion composed of a plurality of latches or flip-flops whose data input terminals are connected together and whose clock input terminals are connected together, and
a coincidence checker that checks whether or not output signals of the plurality of latches or flip-flops coincide with each other, and
the register circuit sends an output signal of the coincidence checker to a following stage as a final register output.

7. The semiconductor device of claim 6, wherein
the register circuit includes, as the coincidence checker, an AND logic unit that takes an AND of the output signals of the plurality of latches or flip-flops, or a majority operation circuit that performs majority operation on the output signals of the plurality of latches or flip-flops.

8. The semiconductor device of claim 6, wherein
the register circuit includes, as the plurality of latches or flip-flops, both a non-inverting output latch or flip-flop and an inverting output latch or flip-flop, and
of the output signals of the plurality of latches or flip-flops, a non-inverting output signal is directly inputted to the coincidence checker, and an inverting output signal is inputted, after a logic level thereof is re-inverted, to the coincidence checker.

9. The semiconductor device of claim 6, wherein
in a circuit block, the plurality of latches or flip-flops are arranged away from each other.

10. The semiconductor device of claim 9, wherein
in the circuit block, the plurality of latches or flip-flops are arranged in such a way that conductor lengths from a signal branch part at which the data input terminals thereof are connected together and the clock input terminals thereof are connected together to the respective latches or flip-flops are equal to each other.

11. A semiconductor device comprising:
a first register circuit that holds an input data signal according to a clock signal;
a monitoring circuit that receives an output signal of the first register circuit, an operating status signal indicating an operating status of a controlled apparatus, and a monitoring level setting signal used for setting requirements for permission to generate an enable signal, and that generates the enable signal according to the input data signal only when the operating status of the controlled apparatus satisfies the requirements for permission to generate the enable signal;
a second register circuit that holds the enable signal according to the clock signal;
a logic circuit that is so configured that, based on an output signal of the second register circuit, read operation of a control signal and generation operation of an output data signal according to the control signal are permitted/prohibited, and that generates the operating status signal one after another based on the operating status of the controlled apparatus;
an output circuit that controls operations of the controlled apparatus based on the output data signal; and
a control circuit that generates the monitoring level setting signal according to an external instruction, wherein
the first register circuit and the second register circuit each include
a register portion composed of a plurality of latches or flip-flops whose data input terminals are connected together and whose clock input terminals are connected together, and
a coincidence checker that checks whether or not output signals of the plurality of latches or flip-flops coincide with each other, and
the first register circuit and the second register circuit each send an output signal of the coincidence checker to a following stage as a final register output.

12. The semiconductor device of claim 11, wherein
the first register circuit and the second register circuit each include, as the coincidence checker, an AND logic unit that takes an AND of the output signals of the plurality of latches or flip-flops, or a majority operation circuit that performs majority operation on the output signals of the plurality of latches or flip-flops.

13. The semiconductor device of claim 11, wherein
the first register circuit and the second register circuit each include, as the plurality of latches or flip-flops, both a non-inverting output latch or flip-flop and an inverting output latch or flip-flop, and
of the output signals of the plurality of latches or flip-flops, a non-inverting output signal is directly inputted to the coincidence checker, and an inverting output signal is inputted, after a logic level thereof is re-inverted, to the coincidence checker.

14. The semiconductor device of claim 11, wherein
in a circuit block, the plurality of latches or flip-flops are arranged away from each other.

15. The semiconductor device of claim 14,
in the circuit block, the plurality of latches or flip-flops are arranged in such a way that conductor lengths from a signal branch part at which the data input terminals thereof are connected together and the clock input terminals thereof are connected together to the respective latches or flip-flops are equal to each other.

16. An electric appliance comprising:
a controlled apparatus; and
a semiconductor device that controls operations of the controlled apparatus, wherein
the semiconductor device includes
a first register circuit that holds an input data signal according to a clock signal,
a monitoring circuit that receives an output signal of the first register circuit, an operating status signal indicating an operating status of the controlled apparatus, and a monitoring level setting signal used for setting requirements for permission to generate an enable signal, and that generates the enable signal according to the input data signal only when the operating status of the controlled apparatus satisfies the requirements for permission to generate the enable signal,
a second register circuit that holds the enable signal according to the clock signal,
a logic circuit that is so configured that, based on an output signal of the second register circuit, read operation of a control signal and generation operation of an output data signal according to the control signal are permitted/prohibited, and that generates the operating status signal one after another based on the operating status of the controlled apparatus,
an output circuit that controls operations of the controlled apparatus based on the output data signal, and
a control circuit that generates the monitoring level setting signal according to an external instruction,
the first register circuit and the second register circuit each include
a register portion composed of a plurality of latches or flip-flops whose data input terminals are connected together and whose clock input terminals are connected together, and
a coincidence checker that checks whether or not output signals of the plurality of latches or flip-flops coincide with each other, and
the first register circuit and the second register circuit each send an output signal of the coincidence checker to a following stage as a final register output.
